(19) United States
(12) Patent Application Publication
(10) Pub. No.: US 2004/0183202 A1
(43) Pub. Date: Sep. 23, 2004

(54) Semiconductor device having copper damascene interconnection and fabricating method thereof

(75) Inventor: Tatsuya Usami, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/766,886

(22) Filed: Jan. 30, 2004

(30) Foreign Application Priority Data
Jan. 31, 2003 (JP) 2003-024716
Dec. 18, 2003 (JP) 2003-420838
Dec. 18, 2003 (JP) 2003-420839

(51) Int. Cl. H01L 23/48

(52) U.S. Cl. 257/762

(57) ABSTRACT

A silicon carbon nitride film is formed on an interlayer dielectric film having Si—H bonds and a Cu interconnection. The silicon carbon nitride film has the role of blocking moisture absorption and prevents deterioration associated with the moisture absorption by a lower-layer insulating film and a Cu film, thereby suppressing an increase in the capacitance between interconnections or via resistance. The effect is great especially when the nitrogen concentration of the silicon carbon nitride film is not less than 10 atm % but less than 35 atm %. Between the interlayer dielectric film having Si—H bonds and the Cu interconnection is interposed a laminated film of a Ta film and a TaN film as a barrier metal film in such a manner that the TaN film becomes on the side of the interlayer dielectric film. Because the TaN film prevents the occlusion of the H in the interlayer dielectric film into the Ta film, the deterioration of the Ta film is suppressed and peeling is suppressed in steps such as CMP.

### BACKGROUND OF THE INVENTION

1. Field of the Invention

The present invention relates to a semiconductor device and a fabricating method of the semiconductor device and, more particularly, to a high-reliability semiconductor device of an interconnection structure using a low-dielectric-constant interlayer dielectric film and a low-dielectric-constant barrier insulating film.

2. Description of the Related Art

In recent years, requirements for higher speeds of signal processing of LSIs have been increasing year by year. The signal processing speed of LSIs is determined mainly by the working speed of a transistor itself and a signal propagation delay time in interconnections. The working speed of a transistor which has had a great effect on the signal processing speed of LSIs has hitherto been improved by scaling down transistors. However, in LSIs whose design rule is smaller than 0.25 micron, an effect related to a signal propagation delay time in interconnections, which is the latter factor, has begun to appear. This effect is great especially in LSI devices having multilayer interconnections.

Therefore, as a method of improving a signal propagation delay in interconnections, the hitherto used aluminum interconnections have been replaced with copper interconnections. Furthermore, the replacement of the hitherto used silicon oxide film with a low-dielectric-constant interlayer dielectric film is under study. Among such low-dielectric-constant interlayer dielectric layers, the mass production using a hydrogenated polysiloxane, which is one of the films capable of realizing a relative dielectric constant of not more than 3.0, has been carried out for aluminum interconnections and mass production is under study for Cu interconnections. Among others, L-Ox (ladder oxide, trade name: Ladder Oxide), which is a ladder-type hydrogenated polysiloxane, has Si—H bonds in part of the Si—O skeleton and is constituted from inorganic materials and, therefore, L-Ox has better adhesion to interconnection metals than organic materials. Furthermore, because of its ladder structure, L-Ox has excellent resistance to plasma ashing and organic peeling liquids and hence deteriorated layers such as humidified layers by the treatments are not formed on processed surfaces.

On the other hand, a barrier insulating film which serves to prevent Cu diffusion and functions as a stopper film of etching for Cu damascene processes is also required to provide low-dielectric-constant design, and the replacement of the conventional silicon nitride film having a relative dielectric constant of about 7.0 with insulating films based on a silicon carbide film (hereinafter referred to as a “SiC film”) having a relative dielectric constant of less than 5.0 is under study. An example in which a film is formed by plasma CVD by use of trimethylsilane and an inert gas has been reported.

Also, barrier metals are used as a barrier against the diffusion of Cu to interlayer dielectric layers in association with the use of Cu interconnections and as an adhesion layer to an insulating film. In particular, Ta-base barrier metal films are being mass produced. When it is necessary to assure the reliability of the Cu/Low-k structure for scale down design, mass production can be realized only when combinations of the above-described low-dielectric interlayer dielectrics, barrier insulating films and barrier metal films are optimized.

Next, an example of a structure of a semiconductor device in which a conventional low-dielectric-constant interlayer dielectric film, a barrier insulating film and a barrier metal film are used will be described by referring to drawings. As shown in FIG. 14, a 0-th barrier insulating film 502 is formed on a lower-layer insulating film 501, and a first low-dielectric-constant film 503 is formed on the 0-th barrier insulating film 502. On top of the first low-dielectric-constant film 503, a first SiO₂ film 504 is formed. An interconnection trench is formed in an interlayer dielectric film which is formed by the laminating of the above-described 0-th barrier insulating film 502, first low-dielectric-constant film 503 and first SiO₂ film 504, and a first barrier metal film 505 is formed in this interconnection trench. A first Cu damascene interconnection is embedded and formed by a first Cu film 506 on the inner side of the first barrier metal film 505. A first barrier insulating film 507 is formed on this Cu damascene interconnection, and on top of the first barrier insulating film 507, a second low-dielectric-constant film 508 and a second SiO₂ film 509 are similarly formed.

A via trench is formed in an interlayer dielectric film which is formed by the laminating of the above-described first barrier insulating film 507, second low-dielectric-constant film 508 and second SiO₂ film 509. As with the above-described Cu interconnection, a second barrier metal film 510 is formed in this via trench, and on the inner side of the second barrier metal film 510, a second Cu film 511 is embedded. A second barrier insulating film 512 is formed on this via, and on top of the second barrier insulating film 512, a third low-dielectric-constant film 513 and a third SiO₂ film 514 are similarly formed. Similarly, a third barrier metal film 515 is formed in an interconnect interlayer insulating film which is formed by the laminating of the above-described second barrier insulating film 512, third low-dielectric-constant film 513 and third SiO₂ film 514, and on the inner side of the third barrier metal film 515, a third Cu film 516 is embedded to form a second Cu damascene interconnection. A third barrier insulating film 517 is formed on this second Cu damascene interconnection. By further repeating this structure as required, a barrier insulating film is formed on a top-layer interconnection (corresponding to the second Cu damascene interconnection in this configuration) and a top-layer low-dielectric-constant film (corresponding to the third low-dielectric-constant film in this configuration). To a top-layer interconnection is connected an aluminum bonding pad 520 (having TiN layers 519, 521 above and below thereof), which is formed in an SiO₂ film 518 through an opening provided in the barrier insulating film, and with the exception of part of this aluminum bonding pad 520, the semiconductor device is coated, through an SiO₂ film 522, with a cover film 523 (an SiON film or an SiN film) having the function of blocking moisture absorption, whereby a multilayer interconnection structure is formed.

Next, a fabricating method of the above-described conventional semiconductor device will be described by referring to FIGS. 15(a) and (c) to FIGS. 18(a) and (b). First, by use of the plasma CVD process a 0-th barrier insulating film 602 with a film thickness of 50 nm to 100 nm was formed on a lower-layer insulating film 601 formed on a semiconductor substrate including transistors. Subsequently, by performing the application and baking of a first low-dielectric-constant film 603, the film was deposited in a thickness of 150 nm to 350 nm. On top of the first low-dielectric-constant film 603, a first SiO₂ film 604 with a thickness of 50 nm to 200 nm was formed by the plasma CVD process (FIG. 15(a)).

After the application of an antireflection coating film (hereinafter referred to as a “ARC film”) 605 as to this structure by use of the photolithography technology of a 0.14 μm level in terms of a minimum size, a patterned photoresist mask 606 was formed (FIG. 15(b)). By use of this mask, the ARC film 605, the first SiO₂ film 604 and the first low-dielectric-constant film 603 were etched by a gas containing a fluorocarbon-base gas and the etching was stopped on the 0-th barrier insulating film 602.

After that, the photoresist mask was peeled by oxygen plasma ashing and then residues etc. were completely removed by use of a weak amine organic peeling liquid etc. After that, the 0-th barrier insulating-film 602 was removed by total etch back. Furthermore, residues were removed by performing rinsing with an organic peeling liquid. As a result of this, a trench pattern for a first interconnection was formed (FIG. 15(c)).

Next, after degassing treatment and RF etching by Ar ions by use of a sputtering apparatus were performed, a first barrier metal film 607 was formed in a thickness of about 30 nm and a Cu seed film (not shown) was formed in a thickness of about 100 nm without breaking a vacuum. Next, a Cu plating film 609 was formed in a thickness of about 600 nm by performing Cu plating. After that, baking was performed at 200 to 400° C. in a vertical type annealing furnace (FIG. 16(a)).

Next, by use of the metal CMP technology the metal in parts other than the trench was removed and a first Cu damascene interconnection 609 was formed (FIG. 16(b)). Next, a first barrier insulating film 610 with a thickness of 50 to 100 nm was formed by use of a plasma CVD apparatus. Subsequently, a second low-dielectric-constant film 611 and a second SiO₂ film 612 were formed in this order. For the formation of a first via, the photolithography technology is used, and a second photoresist mask 614 was formed by use of the photolithography technology on a second ARC film 613 as a via pattern (FIG. 16(c)).

By use of this mask, the second ARC film 613, the second first SiO₂ film 612 and the second low-dielectric-constant film 611 were etched and the etching was stopped on the first barrier insulating film 610, whereby a first via trench was opened. After that, the photoresist mask was peeled by oxygen plasma ashing and then residues etc. were completely removed by use of an amine-base organic peeling liquid etc.

After that, the first barrier insulating film 610 on the bottom of the first via trench was removed and total etch back was performed in order to provide electrical conduction to the first Cu damascene interconnection. Furthermore, residues were removed by performing rinsing with an organic peeling liquid and a trench pattern for the first via was formed. Subsequently, after degassing treatment and RF etching by Ar ions by use of a sputtering apparatus were performed in this order, a second barrier metal film 615 was formed in a thickness of about 30 nm and a Cu seed film (not shown) was formed in a thickness of about 100 nm without breaking a vacuum. Next, a copper plating film 617 was formed in a thickness of about 300 nm by performing Cu plating. After that, baking was performed at 200 to 400° C. in a vertical type annealing furnace. Next, by use of the metal CMP technology the metal in parts other than a via was removed and a via 617 was formed. (FIG. 17(a)).

Next, a second barrier insulating film 618 with a thickness of 50 to 100 nm was formed by use of a plasma CVD apparatus. Subsequently, a third low-dielectric-constant film 619 and a third SiO₂ film 620 were formed in this order (FIG. 17(b)) After the application of a third ARC film 621 to this structure, a patterned third photoresist mask 622 was formed by use of the photolithography technology of a 0.14/0.14 μm level in terms of a minimum of Line/Space (FIG. 18(a)).

By use of this mask, the third ARC 621, the third SiO₂ film 620 and the third low-dielectric-constant film 619 were etched by a gas containing a fluorocarbon-base gas and the etching was stopped on the second barrier insulating film 618, whereby a trench pattern for a second interconnection was opened. After that, the photoresist mask was peeled by oxygen plasma ashing and then residues etc. were completely removed by use of an amine-base organic peeling liquid etc.

After that, the second barrier insulating film 618 on the bottom of the trench for the second interconnection was removed by total etch back. Furthermore, residues were removed by performing rinsing with an organic peeling liquid. As a result of this, a trench pattern for a second interconnection was formed. Subsequently, as with the first interconnection, after degassing treatment and RF etching by Ar ions by use of a sputtering apparatus were performed, a third barrier metal film 623 was formed in a thickness of about 30 nm and a Cu seed film was formed in a thickness of about 100 nm without breaking a vacuum. Next, a copper film 624 was formed in a thickness of about 600 nm by performing Cu plating. After that, baking was performed at 200 to 400° C. in a vertical type annealing furnace. After that, a second Cu damascene interconnection was formed by performing metal CMP and a third barrier insulating film 625 was formed on this second Cu trench interconnection (FIG. 18(b)).

After that, an SiO₂ interlayer dielectric film with a thickness of 300 to 500 nm was formed on this third barrier insulating film 625 by the plasma CVD process, and by use of the photolithography technology a photoresist mask for providing an opening on the second Cu damascene interconnection was formed on the third barrier insulating film 625 and the SiO₂ interlayer dielectric film. Subsequently, by etching the exposed SiO₂ interlayer dielectric film and the third barrier insulating film 625, an opening for connecting the second Cu damascene interconnection and the bonding pad together was formed. After the removal of the photoresist mask, the TiN film 519 with a thickness of 100 to 200 nm, the Al—Cu (0.5%) film 520 with a thickness of 800 to 1000 nm and the TiN film 521 with a thickness of 50 to 100 nm were formed in this order by the sputtering process. Subsequently, by use of the photolithography technology a photoresist mask for forming a bonding pad was formed and the photoresist mask was removed after the formation of the bonding pad by the etching step. The SiO₂ film 522 with a thickness of 100 to 200 nm and the SiON film 523 with a thickness of 100 to 200 nm were formed in this order by the plasma CVD process so as to cover the TiN film 521 on the bonding pad, and by use of the photolithography technology prescribed regions of the SiON film, SiO₂ film and TiN film 521 were opened, whereby the bonding pad was exposed and the semiconductor device shown in FIG. 14 was obtained.

The above-described conventional fabricating method of semiconductor devices is an example of the single damascene process. However, fabricating methods by the dual damascene process are also publicly known. The National Publication of International Patent Application No. 2002-526916 describes a semiconductor device of the dual damascene structure in which a silicon glass doped with fluorine (FSG) as a low-dielectric-constant interlayer dielectric film and an SiC film as a low-dielectric-constant barrier film are used. The U.S. Pat. No. 6,417,092 describes a semiconductor device in which a carbon-doped silicon oxide as a low-dielectric-constant interlayer dielectric film and an amorphous material containing silicon, carbon, nitrogen and hydrogen as a barrier film which serves also as an etching stopper are used. Furthermore, the Japanese Patent Laid-Open No. 2001-326222 describes a semiconductor device of the dual damascene structure in which an MSQ (methylsilsesquioxane) film and MHSQ (methylated hydrogensilsesquioxane) as low-dielectric-constant interlayer dielectric films and a Ta film as a barrier metal film are used. It is known that similarly, a TaN film is also used as a barrier metal film.

When the present inventor used L-Ox as a low-dielectric-constant interlayer dielectric film and an SiC film as a barrier insulating film in the fabrication of a semiconductor device of the above-described damascene interconnection structure, a problem in electrical properties arose because the fabricating process required a long time. Furthermore, irrespective of the types of insulating film, the surface and interface of the Cu interconnection were oxidized. In particular, there were problems of a rise in via resistance and an increase in the capacitance between interconnections. Furthermore, when a Ta single-layer film was used as a barrier metal film, peeling occurred at the interface between the L-Ox film and the Ta film during the CMP process for the formation of the first and second damascene interconnections and the via. Also, when the TaN single-layer film was used in place of the Ta film, the poor wettability of Cu by the TaN film posed the problem that Cu cannot be sufficiently embedded in the via of high aspect ratio etc.

### SUMMARY OF THE INVENTION

The present invention has as its object the provision of a high-reliability semiconductor device of a Cu damascene interconnection structure using a low-dielectric-constant interlayer dielectric film and a fabricating method of this semiconductor device. That is, the invention has as its object the provision of a semiconductor device in which an increase in the capacitance between interconnections, the oxidation of a Cu interconnection, etc. due to along-duration manufacturing process are suppressed and a manufacturing method of this semiconductor device. Furthermore, the invention has as its object the provision of a semiconductor device which has good adhesion of an interlayer dielectric to a barrier metal film and good Cu embeddability during the fabrication of a Cu damascene interconnection structure and a fabricating method of this semiconductor device.

In a semiconductor device of the present invention, an interlayer dielectric film having Si—H bonds is provided on a base layer including a semiconductor substrate and a silicon carbon nitride film is formed on the interlayer dielectric film. Furthermore, an electrically conductive film containing Cu as a main component element is embedded in a trench formed in the interlayer dielectric film and the silicon carbon nitride film is formed on the electrically conductive film. The interlayer dielectric film and the electrically conductive film are each formed in a plurality of layers and the silicon carbide nitride film is formed so as to cover the electrically conductive film and interlayer dielectric film each in a top layer. Desirably, this silicon carbon nitride film has a nitrogen concentration of not less than 10 atm % but less than 35 atm % and, more desirably, it has a nitrogen concentration of not less than 15 atm % but not more than 30 atm %. Preferably, the silicon carbon nitride film contains, as other components, not less than 22 atm % but not more than 27 atm % Si, not less than 20 atm % but not more than 25 atm % C, and not less than 35 atm % but not more than 45 atm % H. Also, the silicon carbon nitride film further contains not less than 0.5 atm % but less than 5 atm % O. The interlayer dielectric film having Si—H bonds is a ladder-type hydrogenated polysiloxane film or a porous ladder-type hydrogenated polysiloxane film. A metal nitride film is provided between the interlayer dielectric film and the electrically conductive film containing the Cu as a main component element and a metal film is provided between the electrically conductive film containing the Cu as a main component element and the metal nitride film. The electrically conductive film containing Cu as a main component element is a Cu alloy film containing at lest one kind selected from the group consisting of Al, Si, Ag, W, Mg, Bi, Zn, Pd, Cd, Au, Hg, Be, Pt, Zr, Ti and Sn. Furthermore, the electrically conductive film containing Cu as a main component element is a Cu alloy film containing Si and the Si content is highest on a top surface of the electrically conductive film and gradually decreases with increasing depth in the direction of a bottom surface.

Also, in a semiconductor device of the present invention, an interlayer dielectric film having Si—H bonds and an electrically conductive film containing Cu as a main component element are provided on a base layer including a semiconductor substrate, a metal nitride film is provided between the interlayer dielectric film and the electrically conductive film containing Cu as a main component element, and a metal film is provided between the electrically conductive film containing Cu as a main component element and the metal nitride film. The electrically conductive film containing Cu as a main component element is buried in a trench formed in the the interlayer dielectric film. The metal film is Ta and the metal nitride film is TaN. Desirably, the TaN has a nitrogen content of not less than 15 atm % and, more desirably, it has a nitrogen concentration of not less than 15 atm % but less than 40 atm %. The interlayer dielectric film having Si—H bonds is either a hydrogenated polysiloxane film or a hydrogenated organopolysiloxane film. The hydrogenated polysiloxane film is a ladder-type hydrogenated polysiloxane film or a porous ladder-type hydrogenated polysiloxane film. The electrically conductive film containing Cu as a main component element is a Cu alloy film containing at lest one kind selected from the group consisting of Al, Si, Ag, W, Mg, Bi, Zn, Pd, Cd, Au, Hg, Be, Pt, Zr, Ti and Sn. The electrically conductive film containing Cu as a main component element is a Cu alloy film containing Si and the Si content is highest on a top surface of the electrically conductive film and gradually decreases with increasing depth in the direction of a bottom surface.

A fabricating method of a semiconductor device of the invention includes: the first step of forming an interlayer dielectric film having Si—H bonds on a semiconductor substrate; the second step of forming a trench in the interlayer dielectric film; the third step of forming a barrier metal film on a side wall and bottom surface of the trench; the fourth step of embedding an electrically conductive film containing Cu as a main component element in the trench in which the barrier metal film is formed; and the fifth step of forming a silicon carbon nitride film on the interlayer dielectric film and the electrically conductive film. The third step involves forming a barrier metal film which is formed by sequentially laminating a metal nitride film and a metal film on a side wall and bottom surface of the trench. The electrically conductive film containing Cu as a main component element is an Si-containing film in which a Cu film is subjected to silane treatment.

Also, a fabricating method of a semiconductor device of the present invention includes: the first step of forming an interlayer dielectric film having Si—H bonds on a semiconductor substrate; the second step of forming a trench in said interlayer dielectric film; the third step of forming a barrier metal film which is formed by sequentially laminating a metal nitride film and a metal film on a side wall and bottom surface of the trench; and the fourth step of embedding an electrically conductive film containing Cu as a main component element in the trench in which the barrier metal film is formed. The electrically conductive film containing Cu as a main component element is an Si-containing film in which a Cu film is subjected to silane treatment. The first step is a step in which after the formation of an interlayer dielectric film containing Si as a main component element, hydrogen is caused to diffuse to the interlayer dielectric film thereby to form the Si—H bonds. The diffusion treatment of hydrogen is any of plasma treatment, electron beam treatment, radical treatment and ion implantation treatment.

The present inventors pursued the clarification of the causes of the increase in the capacitance between interconnections and the oxidation of Cu interconnections, which occurred during the fabrication of conventional semiconductor devices by a long-duration fabricating process. As a result, they found out the reason that none of the L-Ox film, SiO₂ film and SiC film constituting conventional semiconductor elements has the sufficient function of blocking moisture absorption. That is, the present inventors found out that the increase in the capacitance between interconnections and the oxidation of Cu interconnections had been brought about by moisture absorption. In the present invention, a silicon carbon nitride film is used in an upper layer of an interlayer dielectric film having Si—H bonds, such as a hydrogenated polysiloxane represented by an L-Ox film. This silicon carbon nitride film has the function of blocking moisture absorption. Therefore, even when a film having no moisture absorption resistance such as a hydrogenated polysiloxane is used in a lower layer, the silicon carbon nitride film suppresses the penetration of moisture from the outside into the film having no moisture absorption resistance and hence can suppress an increase in the capacitance between interconnections. Furthermore, this silicon carbon nitride film is formed on an electrically conductive film having Cu as a main component element. Because the surface of the electrically conductive film is covered with a film having moisture absorption resistance, the oxidation of the electrically conductive film is suppressed. In addition, problems of an increase in via resistance etc. do not arise. The larger the number of Si—H bonds in the interlayer dielectric film, the more remarkably the above-described effect will be observed. Therefore, when an interlayer dielectric film having Si—H bonds is used as a low-dielectric-constant film, a combined use of a silicon carbon nitride film as a barrier insulating film is suitable for providing a high-reliability semiconductor device in which electric properties do not deteriorate due to the effect of humidity. It is preferred that the silicon carbon nitride film be formed so as to cover the electrically conductive film and the interlayer dielectric film having Si—H bonds in the top layer.

Also, the present inventors pursued the clarification of the cause of the peeling at the interface between an L-Ox film and a Ta film, which had occurred in the CMP fabrication process of conventional semiconductor devices. As a result, they found that this peeling had been caused by occluding the hydrogen in the L-Ox film constituting conventional semiconductor devices into the Ta film. That is, the present inventors found out that because of the direct contact of the L-Ox film with the Ta film, the hydrogen in the L-Ox film is occluded into Ta, deteriorating the Ta film, with the result that the Ta film has no resistance to high-load processes such as metal CMP. In the present invention, a semiconductor device has such a configuration that an interlayer dielectric film having Si—H bonds, such as a hydrogenated polysiloxane represented by an L-Ox film, is not in direct contact with a barrier metal layer having the function of occluding hydrogen, such as a Ta film. That is, a layer which suppresses the occlusion of the hydrogen in the interlayer dielectric layer into the barrier metal layer is interposed between the two layers. The present inventors found out that a metal nitride film has this suppressing effect and that a nitrogen concentration of a metal nitride film is not less than 15 atm % but less than 40 atm % is especially preferred. In the present invention, when a semiconductor device has such a configuration that the barrier metal layer is laminated by a metal film such as Ta having the function of occluding hydrogen and a film such as TaN suppressing the occlusion of hydrogen, and the metal film is disposed on the Cu interconnection side, it is also possible to form a Cu interconnection having a high aspect ratio, i.e., to ensure good embeddability in a trench provided in the interlayer dielectric film.

### BRIEF DESCRIPTION OF THE DRAWINGS

This above-mentioned and other objects, features and advantages of this invention will become more apparent by reference to the following detailed description of the invention taken in conjunction with the accompanying drawings, wherein:

FIG. 1 is a drawing of a semiconductor device related to the first embodiment of the invention;

FIG. 2 is a drawing of a semiconductor device related to the second embodiment of the invention;

FIG. 3 is a drawing of a semiconductor device related to the third embodiment of the invention;

FIGS. 4(a) to (c), FIGS. 5(a) to (c), FIGS. 6(a) and (b), and FIGS. 7(a) and (b) are drawings of the fabricating steps of the semiconductor device related to the first embodiment of the invention;

FIG. 8 is a drawing which shows the relationship between the nitrogen concentration of a silicon carbon nitride film and the capacitance between interconnections in the first embodiment of the invention;

FIG. 9 is a drawing which shows the relationship between the nitrogen concentration and the relative dielectric constant of a silicon carbon nitride film in the invention;

FIG. 10 is a drawing which shows the relationship between the nitrogen concentration of a silicon carbon nitride film in the invention and the via resistance in the third embodiment of the invention;

FIG. 11 is a drawing which shows the FTIR spectrum of an SiO₂ film/a PSG film before and after the PCT;

FIG. 12 is a drawing which shows the FTIR spectrum of an SiC film/a PSG film before and after the PCT;

FIG. 13 is a drawing which shows the FTIR spectrum of a silicon carbon nitride film/a PSG film before and after the PCT in the invention;

FIG. 14 is a drawing of semiconductor device related to a conventional embodiment; and

FIGS. 15(a) to (c), FIGS. 16(a) to (c), FIGS. 17(a) and (b) and FIGS. 18(a) and (b) are drawings of the fabricating steps of the semiconductor device related to a conventional embodiment.

### DESCRIPTION OF THE PREFERRED EMBODIMENTS

Next, embodiments of a semiconductor device of the present invention will be described by referring to the drawings. Those skilled in the art will recognize that many alternative embodiments can be accomplished using the teachings of the present invention and that the invention is not limited to the embodiments illustrated for explanatory purposes.

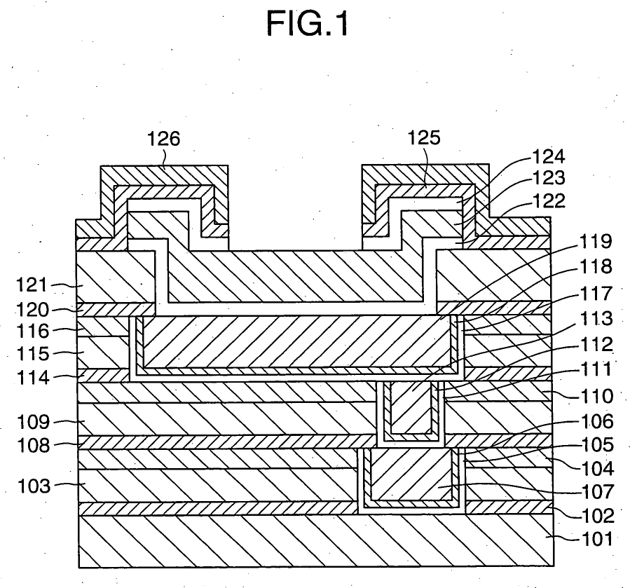

FIG. 1 is a drawing of the first embodiment of a semiconductor device of the invention. As shown in FIG. 1, on a lower-layer insulating film 101, a 0-th silicon carbon nitride film (an insulating film containing as main component elements Si, C, N and H) 102 is formed as a barrier film which serves also as an etching stopper. On top of this 0-th silicon carbon itride film 102, a first L-Ox film 103 which is a ladder-type hydrogenated polysiloxane film is formed. On top of this first L-Ox film 103, a first SiO₂ film 104 is formed. A laminated film of Ta film 106/TaN film 105 (the Ta film in an upper layer and the TaN film in a lower layer) as a first barrier metal is formed in a first interconnection trench which is formed in the 0-th silicon carbon nitride film 102, the first L-Ox film 103 and the first SiO₂ film 104. On the inner side of this first barrier metal, a first Cu film 107 is embedded and a Cu damascene interconnection is formed. A first silicon carbon nitride film 108, which is a barrier insulating film, is formed on this first Cu damascene interconnection, on top of this first silicon carbide nitride film 108, a second L-Ox film 109 and a second SiO₂ film 110 are similarly formed, and a via trench is opened for these films.

Similarly, in a via portion, a Ta film 112/a TaN film 111 are formed as a second barrier metal and on the inner side of this second barrier metal a second Cu film 113 is embedded to form a via. Furthermore, a second silicon carbon nitride film 114, which is a barrier insulating film, is formed on this via, and on top of this second silicon carbon nitride film 114, a third L-Ox film 115 and a third SiO₂ film 116 are each laminated. Similarly, in a second interconnection trench formed in the second silicon carbon nitride film 114, the third L-Ox film 115 and the third SiO₂ film 116, a Ta film 118/a TaN film 117 are formed as a third barrier metal and on the inner side of this third barrier metal a third Cu film 119 is embedded and a second Cu damascene interconnection is formed. A third silicon carbon nitride film 120 is formed on this second Cu damascene interconnection. By further repeating this structure as required, a silicon carbon nitride film is formed on a top-layer interconnection (corresponding to the second Cu damascene interconnection in this embodiment) and a top-layer L-Ox film (corresponding to the third L-Ox film in this embodiment). To the top-layer interconnection is connected an aluminum bonding pad 123 through an opening provided in the silicon carbon nitride film. With the exception of part of this aluminum bonding pad 123 (although a structure having TiN layers 122, 124 as a barrier metal above and below the aluminum is shown by way of example, the present invention is not limited to this structure), the semiconductor device is coated, through an SiO₂ film 125, with a cover film 126 (an SiON film or an SiN film) having the function of blocking moisture absorption, whereby a multilayer interconnection structure is formed. In the semiconductor device thus obtained, the increase in the capacitance between interconnections and the rise in via resistance, which had been observed in conventional semiconductors, were not observed. Furthermore, problems such as the poor Cu embeddability and the peeling of interfaces by CMP which had been observed in conventional semiconductors were not observed.

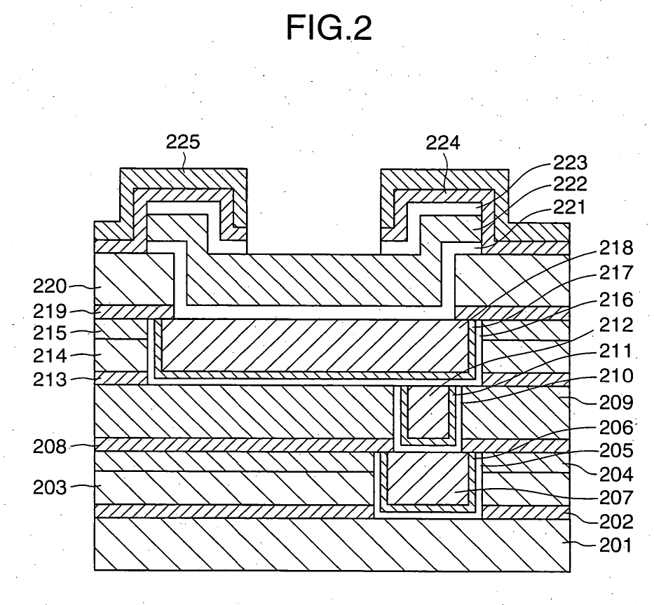

The structure of a semiconductor device by the second embodiment is shown in FIG. 2. The difference from the first embodiment resides in that a via interlayer dielectric film is formed as an SiO₂ single layer. The merit of this structure lies in the stability of electrical properties and the stability of reliability when the TAT of fabrication is very long. It might be thought that this is because the moisture absorption in the via step has an effect on electrical properties and reliability.

In this semiconductor device, a 0-th silicon carbon nitride film 202 is formed on a lower-layer insulating film 201, and on top of this 0-th silicon carbon nitride film 202, a first L-Ox film 203, which is a ladder-type hydrogenated polysiloxane film is formed. On top of this first L-Ox film 203, a first SiO₂ film 204 is formed. A laminated film formed of a Ta film 206/a TaN film 205 (the Ta film in an upper layer and the TaN film in a lower layer) as a first barrier metal is formed in an interconnection trench which is formed in the 0-th silicon carbon nitride film 202, the first L-Ox film 203 and the first SiO₂ film 204. On the inner side of this first barrier metal, a first Cu damascene interconnection 207 in which a Cu film is embedded is formed. A first silicon carbon nitride film 208, which is a barrier insulating film, is formed on this first Cu damascene interconnection, and on top of this first silicon carbide nitride film 208, a second SiO₂ film 209 is formed. A via trench is formed in the first silicon carbon nitride film 208 and the second SiO₂ film 209, similarly in the via portion a Ta film 211/a TaN film 210 are formed as a second barrier metal film, and on the inner side of this second barrier metal, a second Cu film 212 is embedded and a via is formed.

Furthermore, a second silicon carbon nitride film 213, which is a barrier insulating film, is formed on this via, and on top of this second silicon carbon nitride film 213, a third L-Ox film 214 and a third SiO₂ film 215 are each similarly laminated. Similarly, in the second silicon carbon nitride film 213, the third L-Ox film 214 and the third SiO₂ film 215, a Ta film 217/a TaN film 216 are formed as a third barrier metal and on the inner side of this third barrier metal, a third Cu film 218 is embedded and a second Cu damascene interconnection is formed. A third silicon carbon nitride film 219 is formed on this second Cu interconnection. By further repeating this structure as required, a silicon carbon nitride film is formed on a top-layer interconnection (corresponding to the second Cu damascene interconnection in this embodiment) and a top-layer L-Ox film (corresponding to the third L-Ox film in this embodiment). To the top-layer interconnection is connected an aluminum bonding pad 222 through an opening provided in the silicon carbon nitride film. With the exception of part of this aluminum bonding pad 222 (although a structure having TiN layers 221, 223 as a barrier metal above and below the aluminum is shown by way of example, the present invention is not limited to this structure), the semiconductor device is coated, through an SiO₂ film 224, with a cover film 225 (an SiON film or an SiN film) having the function of blocking moisture absorption, whereby a multilayer interconnection structure is formed. In the semiconductor device thus obtained, the increase in the capacitance between interconnections and the rise in via resistance, which had been observed in conventional semiconductors, were not observed. Furthermore, problems such as the poor Cu embeddability and the peeling of interfaces by CMP which had been observed in conventional semiconductors were not observed.

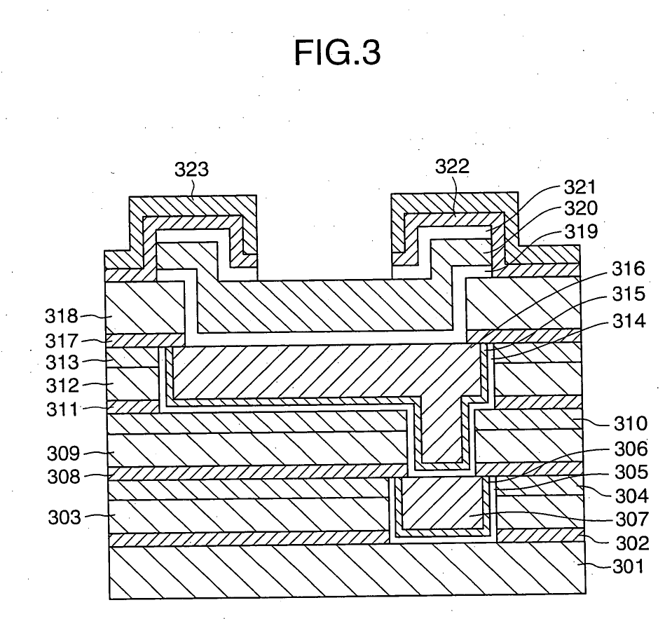

A semiconductor device of the third embodiment is shown in FIG. 3. Unlike the first embodiment, a dual damascene wiring structure was adopted. By using this structure, the number of fabrication steps could be reduced and a decrease in the cost of products could be realized. Furthermore, because it is possible to omit the CMP of vias, this provided the great cost merit that the CMP process, which requires a very high cost, can be omitted. In this semiconductor device, a 0-th silicon carbon nitride film 302 is formed on a lower-layer insulating film 301, and on top of this 0-th silicon carbon nitride film 302, a first L-Ox film 303, which is a ladder-type hydrogenated polysiloxane film is formed. Furthermore on top of this first L-Ox film 303, a first SiO₂ film 304 is formed. A first interconnection trench is formed in the 0-th silicon carbon nitride film 302, the first L-Ox film 303 and the first SiO₂ film 304. In this interconnection trench, a laminated film formed of a Ta film 306/a TaN film 305 (the Ta film in an upper layer and the TaN film in a lower layer) is formed as a first barrier metal.

On the inner side of this first barrier metal, a first Cu damascene interconnection in which a first Cu film 307 is embedded is formed. A first silicon carbon nitride film 308, which is a barrier insulating film, is formed on this first Cu damascene interconnection, and on top of this first silicon carbon nitride film 308, a second L-Ox film 309 and a second SiO₂ film 310 is similarly formed. Furthermore on top of this second SiO₂ film 310, a second silicon carbon nitride film 311 is formed as an etching stopper of a second damascene interconnection, and on top of this second silicon carbon nitride film 311, a third L-Ox film 312 and a third SiO₂ film 313 are laminated. A via which performs electrical connection to the first Cu damascene interconnection and the second Cu interconnection are integrally formed. A second Ta film 315 is formed on a second TaN film 314, and on the inner side of the second Ta film 315, a second Cu film 316 is embedded so that the via and the second Cu damascene interconnection are integrally formed. On this second Cu damascene interconnection, a third silicon carbon nitride film 317 is formed. By further repeating this structure as required, a silicon carbon nitride film is formed on a top-layer interconnection (corresponding to the second Cu damascene interconnection in this embodiment) and a top-layer L-Ox film (corresponding to the third L-Ox film in this embodiment). To the top-layer interconnection is connected an aluminum bonding pad 320 through an opening provided in the silicon carbon nitride film. With the exception of part of this aluminum bonding pad 320 (although a structure having TiN layers 319, 321 as a barrier metal above and below the aluminum is shown by way of example, the present invention is not limited to this structure), the semiconductor device is coated, through an SiO₂ film 322, with a cover film 323 (an SiON film or an SiN film) having the function of blocking moisture absorption, whereby a multilayer interconnection structure is formed. In the semiconductor device thus obtained, the poor Cu embeddability and the peeling of interfaces by CMP, which had been observed in conventional semiconductors, were not observed. Furthermore, problems such as the poor Cu embeddability and the peeling of interfaces by CMP, which had been observed in conventional semiconductors were not observed.

In the above-described first to third embodiments, Cu films were used for interconnections and vias. However, in a case where a Cu alloy film containing at least one kind selected from the group consisting of Al, Si, Ag, W, Mg, Bi, Zn, Pd, Cd, Au, Hg, Be, Pt, Zr, Ti and Sn is used, wettability is better than when Cu is used alone and hence this case provides the merit of use of a Cu alloy film. Particularly when Si is contained, the adhesion to a silicon carbon nitride film is excellent and this effect is great when the distribution of the Si concentration is such that the Si content is highest on a top surface of an electrically conductive film and gradually decreases with increasing depth in the direction of a bottom surface. This distribution can be obtained, for example, by using an inorganic silane gas such as SiH₄, Si₂H₆ and SiH₂Cl₂ as a material gas and treating a Cu film at 250 to 400° C. by use of a plasma CVD apparatus.

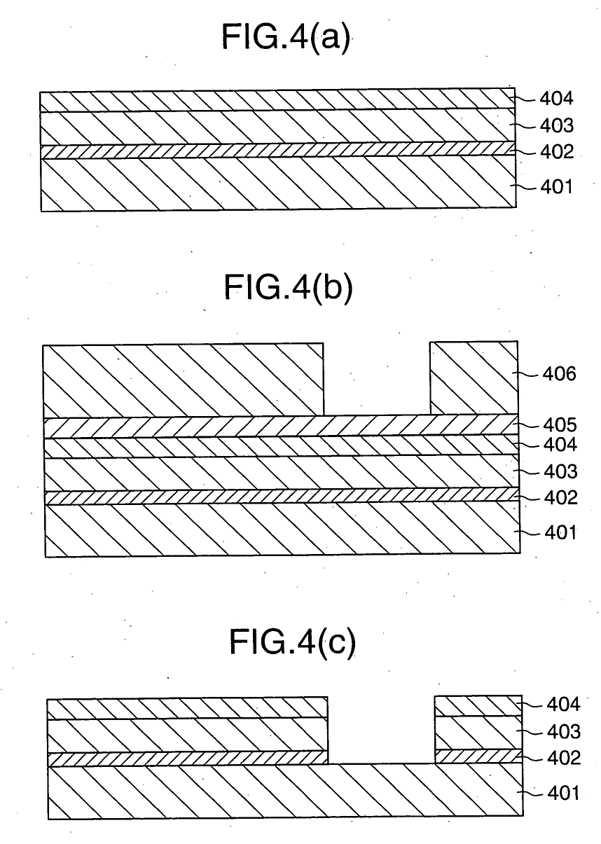

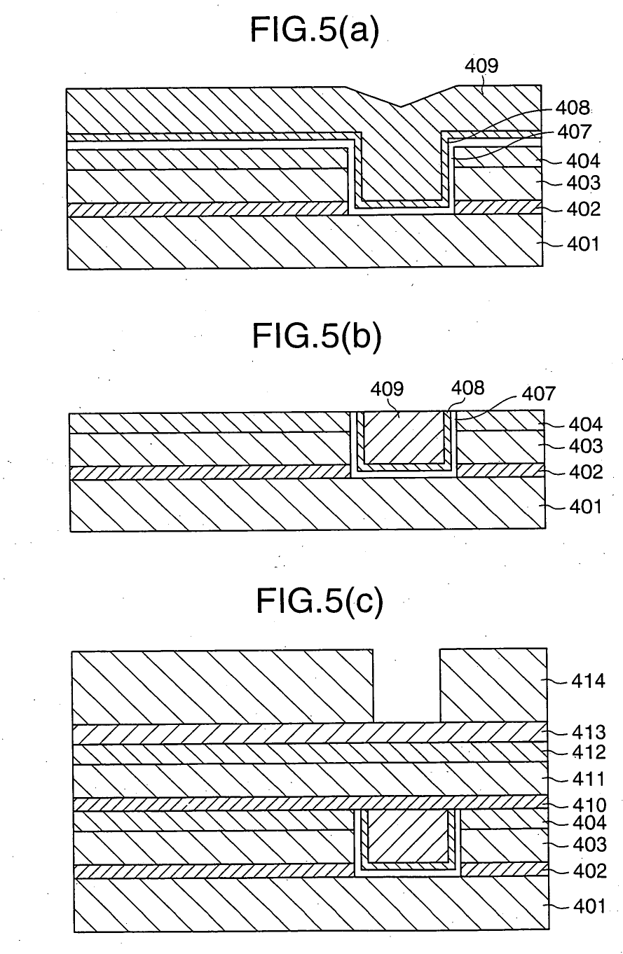

Next, a fabricating method of a semiconductor device in the first embodiment will be described by referring to FIG. 4 to FIG. 7. First, a 0-th silicon carbon nitride film 402 having a film thickness of 50 nm to 100 nm was formed by the plasma CVD process on a lower-layer insulating film 401 including a semiconductor substrate in which a transistor is formed. Subsequently, by performing the application and baking of a first L-Ox film 403, the film was deposited in a thickness of 150 nm to 350 nm. On top of this first L-Ox film 403, a first SiO₂ film 404 in a thickness of 50 nm to 200 nm was formed by the plasma CVD process (FIG. 4(a)). After application of a first ARC film 405 as an antireflection coat to this structure, a patterned first photoresist mask 406 was formed by use of the photolithography technology of a 0.14/0.14 μm level in terms of a minimum of Line/Space (FIG. 4(b)).

By use of this mask, the first ARC film 405, the first SiO₂ film 404 and the first L-Ox film 403 were sequentially etched by a gas containing a fluorocarbon-base gas and a first interconnection trench was opened so that the etching was stopped on the 0-th silicon carbon nitride film 402. After that, the photoresist mask was peeled by oxygen plasma ashing and then residues etc. were completely removed by use of an amine-base organic peeling liquid etc. After that, the 0-th silicon carbon nitride film on the bottom of the first interconnection trench was removed by total etch back. Furthermore, residues were completely removed by performing rinse by use of an organic peeling liquid (FIG. 4(c)).

After degassing treatment and RF etching by Ar ions by use of a sputtering apparatus were performed, a TaN film 407 was formed in a thickness of about 10 nm and subsequently, a Ta film 408 was formed in a thickness of 200 nm as a first barrier metal film on the surface of the substrate (the first SiO₂ film 404) including the interior of the trench (side wall and bottom surface). A Cu seed film (not shown in the figure) was formed in a thickness of about 100 nm without breaking a vacuum. Next, a copper film 409 was formed in a thickness of about 600 nm by Cu plating. (FIG. 5(a)).

After that, baking was performed at 200 to 400° C. in a vertical type annealing furnace. Next, by use of the metal CMP technology the metal in parts other than the trench was removed and a first Cu damascene interconnection for which Cu is embedded in the trench was formed (FIG. 5(b)). Next, by use of a plasma CVD apparatus a first silicon carbon nitride film 410 with a thickness of 50 to 1000 nm was formed. Subsequently, a second L-Ox film 411 with a thickness of 150 to 350 nm and a second SiO₂ film 412 with a thickness of 50 to 200 nm were formed in this order. For the formation of a first via, the photolithography technology is used, and a second photoresist mask 414 was formed on a second ARC film 413 as a via pattern having a diameter of 0.14 μm (FIG. 5(c).

By use of this mask, the second ARC film 413, the second SiO₂ film 412 and the second L-Ox film 411 were etched in this order and a via trench was opened by stopping the etching on the first silicon carbon nitride film 410. Next, the photoresist mask and the second ARC film were removed by plasma ashing and then residues were removed by use of an organic peeling liquid. After that, the first silicon carbon nitride film 410 on the bottom of the via trench was removed and total etching was performed in order to provide electrical conduction to the first Cu damascene interconnection. After that, residues were removed by performing rinse by use of an organic peeling liquid. Subsequently, after degassing treatment and RF etching by Ar ions by use of a sputtering apparatus were performed, a TaN film 415 with a thickness of about 10 nm and a Ta film 416 A with a thickness of 20 nm as a second barrier metal film are formed on the surface of the substrate (the second SiO₂ film 412) including the interior of the via trench(side wall and bottom surface). Subsequently, a Cu seed film (not shown in the figure) was formed in a thickness of about 100 nm without breaking a vacuum. Next, a copper film 417 was formed in a thickness of about 300 nm by performing Cu plating. After that, baking was performed at 200 to 400° C. in a vertical type annealing furnace. Next, by use of the metal CMP technology the metal in parts other than the via was removed and a via for which Cu is embedded in the trench was formed (FIG. 6(a)).

Next, by use of a plasma CVD apparatus a second silicon carbon nitride film 418 with a thickness of 50 to 100 nm was formed. Subsequently, a third L-Ox film 419 with a thickness of 150 to 350 nm and a third SiO₂ film 420 with a thickness of 50 to 200 nm were formed in this order (FIG. 6(b)).

After the application of a third ARC film 421 as an antireflection coat to this structure, a patterned third photoresist mask 422 was formed by use of the photolithography technology of a 0.14/0.14 μm level in terms of a minimum of Line/Space (FIG. 7(a)).

By use of this mask, the third ARC film 421, the third SiO₂ film 420 and the third L-Ox film 419 were etched in this order by a gas containing a fluorocarbon-base gas and a second interconnection trench was opened so that the etching was stopped on the second silicon carbon nitride film 418. After that, the photoresist mask was peeled by oxygen plasma ashing and then residues etc. were completely removed by use of an amine-base organic peeling liquid etc. After that, the second silicon carbon nitride film 418 on the bottom of the second interconnection trench was removed by total etch back. Furthermore, residues were removed by performing rinse by use of an organic peeling liquid. Subsequently, after degassing treatment and RF etching by Ar ions by use of a sputtering apparatus were performed, a TaN film 423 with a thickness of about 10 nm and a Ta film 424 with a thickness of 20 nm were formed as a third barrier metal film. A Cu seed film (not shown in the figure) was formed in a thickness of about 100 nm without breaking a vacuum. Next, a copper film 425 was formed in a thickness of about 600 nm by performing Cu plating. After that, baking was performed at 200 to 400° C. in a vertical type annealing furnace. Next, by use of the metal CMP technology the metal in parts other than the trench was removed and a second Cu damascene interconnection for which Cu is embedded in the trench was formed. Next, by use of a plasma CVD apparatus a third silicon carbon nitride film 426 with a thickness of 50 to 100 nm was formed. (FIG. 7(b)).

After that, an SiO₂ interlayer dielectric film 427 with a thickness of 300 to 500 nm was formed by the plasma CVD process on the third silicon carbon nitride film 426 (corresponding to the third silicon carbon nitride film 120 of FIG. 1), and a photoresist mask for providing an opening on the second Cu damascene interconnection was formed on the third silicon carbon nitride film 426 and SiO₂ interlayer dielectric film 121 by use of the photolithography technology. Subsequently, an opening for connecting the second Cu damascene interconnection to the bonding pad was formed by etching the exposed SiO₂ interlayer dielectric film 121 and the third silicon carbon nitride film 426. After the removal of the photoresist mask, by use of the sputtering process a TiN film 122 with a thickness of 100 to 200 nm, an Al—Cu (0.5%) film 123 with a thickness of 800 to 1000 nm and a TiN film 124 with a thickness of 50 to 100 nm were formed in this order. Subsequently, a photoresist mask for forming a bonding pad was formed by use of the photolithography technology and after the formation of the bonding pad, the photoresist mask was removed by the etching step. An SiO₂ film 125 with a thickness of 100 to 200 nm and an SiON film 126 with a thickness of 100 to 200 nm were formed in this order by the plasma CVD process so as to cover the TiN film 124 on the bonding pad. By use of the photolithography technology prescribed regions of the SiON film 126 and SiO₂ film 125 on the bonding pad 123 were opened, whereby the bonding pad was exposed.

As a result, a semiconductor device having the dual-layer interconnection structure shown in FIG. 1 was obtained. In the formation of this dual-layer interconnection structure, peeling did not occur in CMP and a target value was obtained as the capacitance between interconnections in the measured space of 0.14 μm. Furthermore, in via formation no yield decrease occurred and an increase in via resistance did not occur.

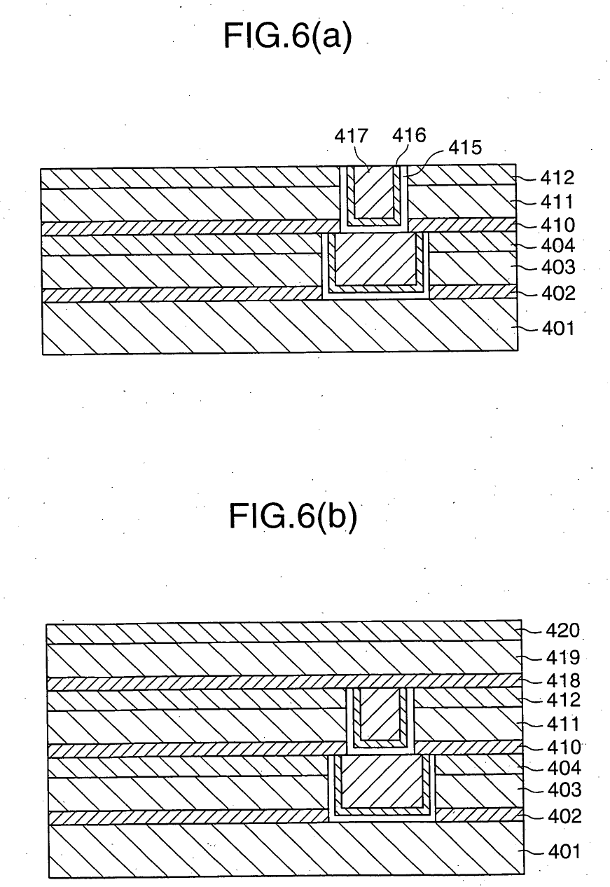

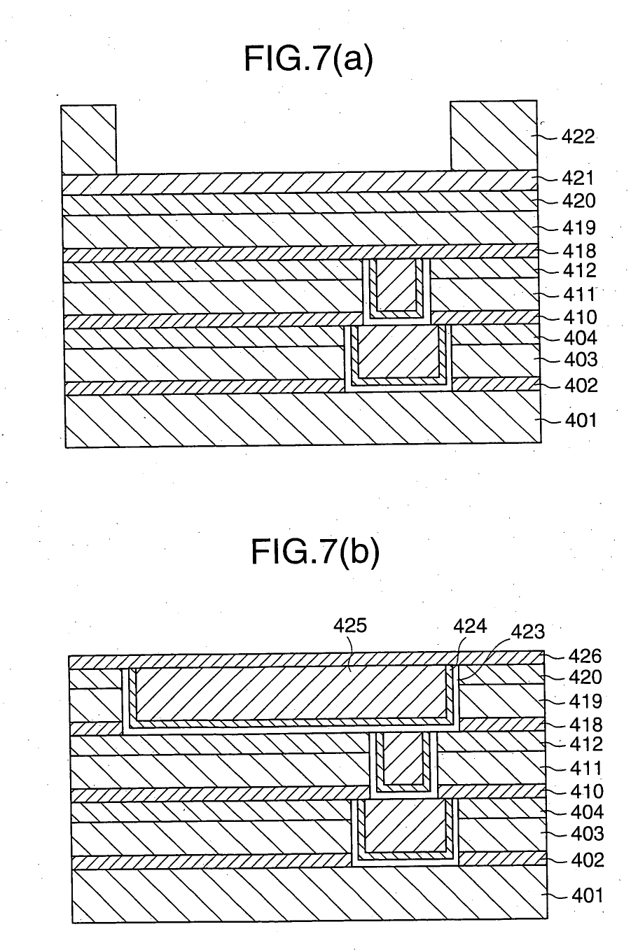

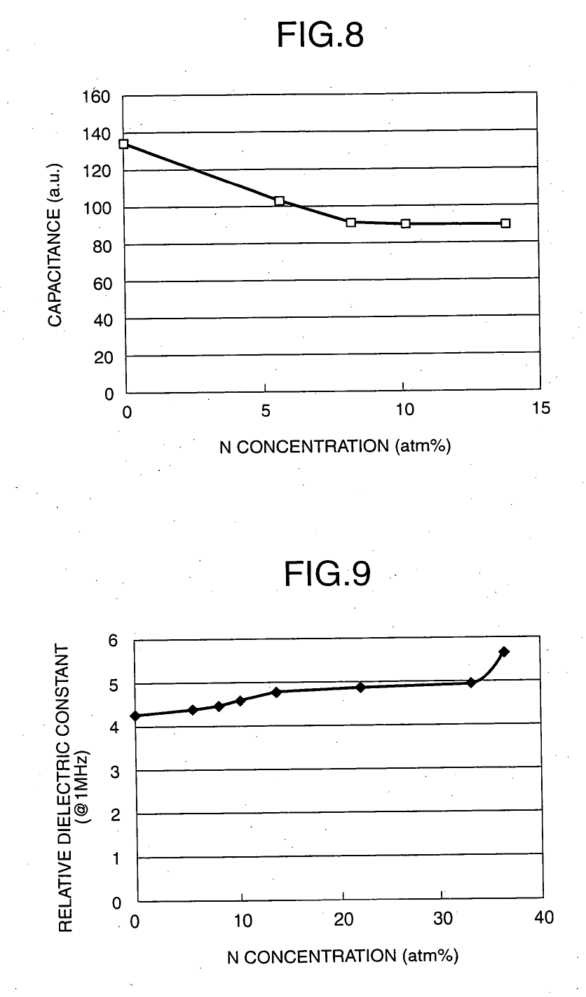

In an experiment conducted by the present inventors, it was found out that the nitrogen concentration of a silicon carbon nitride film used on a Cu interconnection and a Cu via has a great effect on the function of blocking moisture absorption. FIG. 8 shows the relationship between the nitrogen concentration of a silicon carbon nitride film measured by RBS (Backscattering Spectroscopy) as abscissa and the capacitance between interconnections at intervals of line/space=0.14/0.14 μm when the first embodiment is used as ordinate. The capacitance between interconnections decreases with increasing nitrogen concentration of a silicon carbon nitride film and approaches saturation when the nitrogen concentration is not less than about 10 atm % (atomic %). It was ascertained that the capacitance between interconnections is about 15% larger in a case where the nitrogen concentration is 0 than in a case where the nitrogen concentration is not less than 10 atm %.

As shown in FIG. 9, in the case of a silicon carbon nitride film having a nitrogen concentration of not less than 35 atm %, the relative dielectric constant of the film itself increases abruptly to not less than 5.8 and hence the merit of low dielectric constant design in a region of not more than 5.0 is lost. From the foregoing, it is desirable that the nitrogen concentration of a silicon carbon nitride film be not less than 10 atm % but less than 35 atm % and it is more desirable that this nitrogen concentration be not less than 15 atm % but less than 30 atm % from the standpoint of film quality stability.

It has been ascertained that for elements other than nitrogen in a silicon carbon nitride film, the properties of the film are good at an Si concentration in the range of 22 to 27 atm %, a C concentration in the range of 20 to 25 atm % and an H concentration in the range of 35 to 45 atm %, and it might be thought that the above-described relationship holds in these ranges (concentrations of elements other than H were measured by RBS and the H concentration was measured by HFS (Hydrogen Front Scattering Spectroscopy).

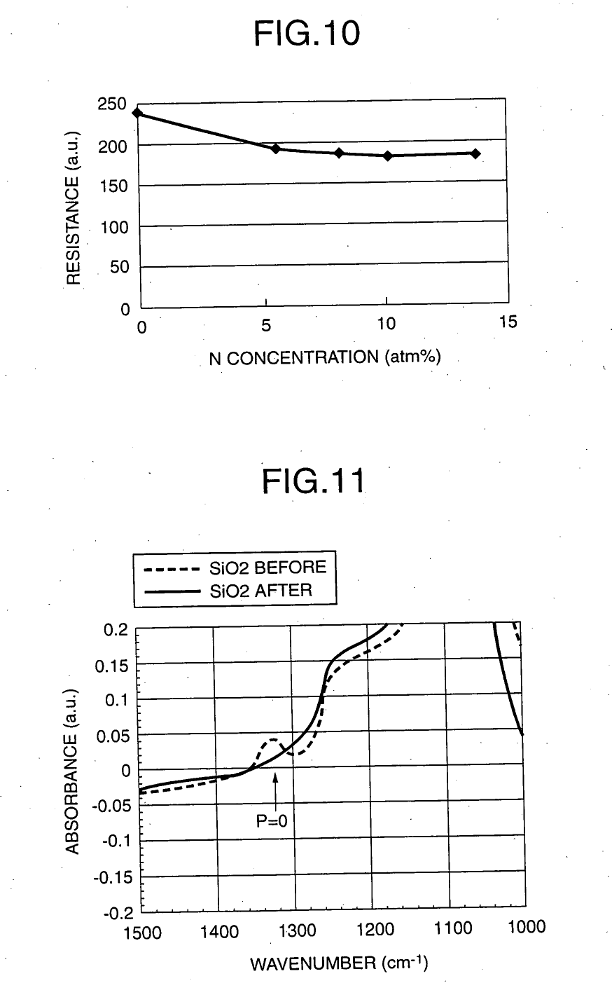

Also, FIG. 10 shows the resistance to a lower-layer Cu interconnection. This figure shows the relationship between the nitrogen concentration of a silicon carbon nitride film as abscissa and the via chain resistance value in the third embodiment as ordinate. The resistance value decreases with increasing nitrogen concentration of a silicon carbon nitride film, and it was ascertained that the resistance of a via enters a saturation range when the nitrogen concentration is not less than about 10 atm %. It was ascertained that in a case where the nitrogen concentration is 0 atm %, peeling occurs and the yield of via chains is low in comparison with a nitrogen concentration of not less than 10 atm % and that the resistance value is about 30% higher in terms of an average value of vias which are not open.

A hydrogenated polysiloxane is used here. However, even when an SiO₂ interlayer dielectric film was used, an increase in via resistance could be confirmed although an increase in the capacitance between interconnections could not be clearly confirmed. And it was also confirmed that when there is a silicon carbon nitride film on a Cu interconnection, reliability tends to decrease irrespective of an interlayer dielectric film when the nitrogen concentration of the film decreases. It has been ascertained that for elements other than nitrogen in a silicon carbon nitride film, the properties of the film are good at an Si concentration in the range of 22 to 27 atm %, a C concentration in the range of 20 to 25 atm % and an H concentration in the range of 35 to 45 atm %, and it might be thought that the above-described relationship holds in these ranges.

From the standpoint of low dielectric constant design, it is preferred that oxygen is further contained in this insulating film. When the O concentration is 1 atm %, the relative dielectric constant can be lowered by about 0.2 in comparison with a case where O is not contained. It has been ascertained that there is no difference in the effect on the suppression of the above-described increase in the capacitance between interconnections if the O concentration is less than 5 atm %. However, because the above-described effect decreases abruptly at an O concentration of not less than 5 atm %, it is desirable that the O concentration be less than 5 atm % and it is more desirable that this O concentration be in the range of 0.5 atm % to 2 atm %. Incidentally, for the hydrogen concentration, the presence of hydrogen is effective in reducing a Cu oxide film and in preventing the oxidation of a Cu interconnection. When the hydrogen concentration is less than 35 atm %, a Cu oxide film is apt to be formed and the resistance value tends to increase.

In order to ascertain that the above-described effect of providing a, silicon carbon nitride film is derived from the function of blocking moisture absorption possessed by this film, the present inventors conducted a test to confirm the function of blocking moisture absorption. As a sample, a silicon carbon nitride film was formed on a totally deposited PSG (Phospho-Silicate Glass) film. In a case where moisture absorption to the PSG cannot be blocked, it is ascertained from the FTIR spectrum that the peak of infrared absorption of P═O bonds in the lower-layer PSG film disappears. As the test to confirm the function of blocking moisture absorption possessed by the silicon carbon nitride film, samples were stored under the PCT (Pressure Cooker Test) conditions of 125° C., 2 atmospheric pressures and a humidity of 100%, and a comparison was made between the FTIR (Fourier Transform Infrared Spectroscopy) spectra before and after the storage under the PCT conditions.

For reference, as shown in FIG. 11, a comparison was also made between the FTIR spectra before and after the PCT for a sample in which an SiO₂ film obtained by the plasma CVD process, which has apparently no function of blocking moisture absorption, was formed on a PSG film. Although P═O bonds present in wave numbers of about 1330 cm⁻¹ were observed before the PCT, they disappeared in the FTIR spectrum after a lapse of 96 hours in the PCT and could not be observed. That is, it could be ascertained that the function of blocking moisture absorption can be checked by this method.

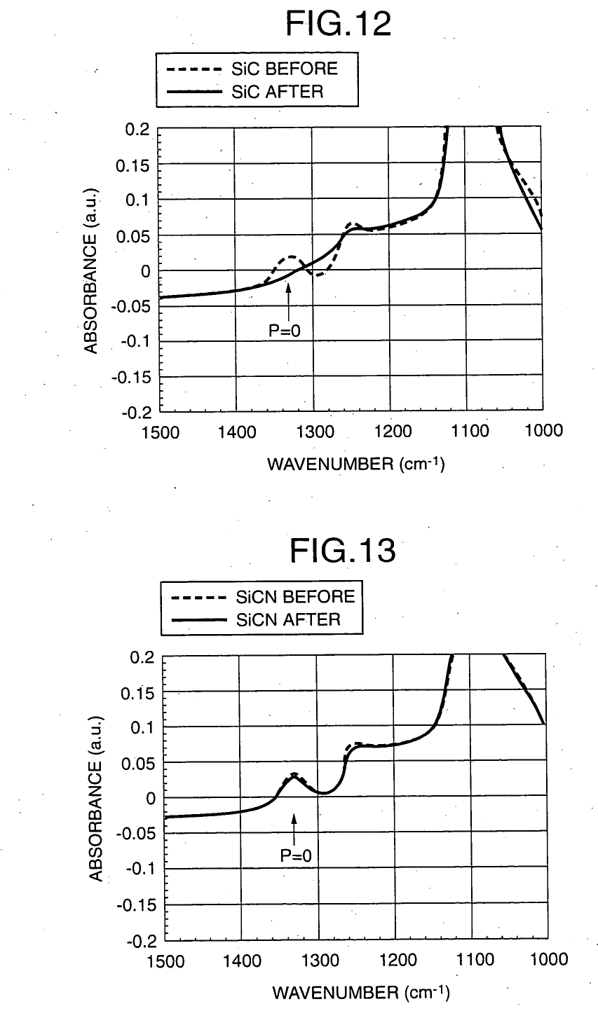

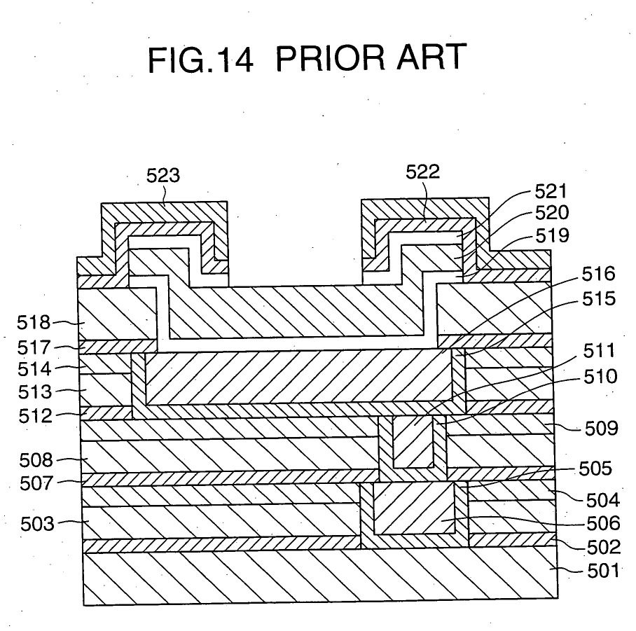

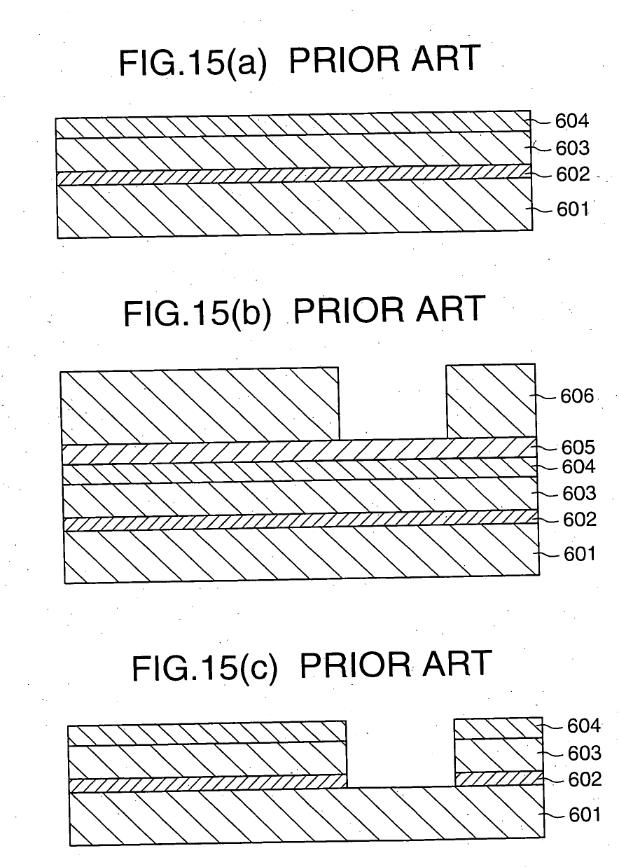

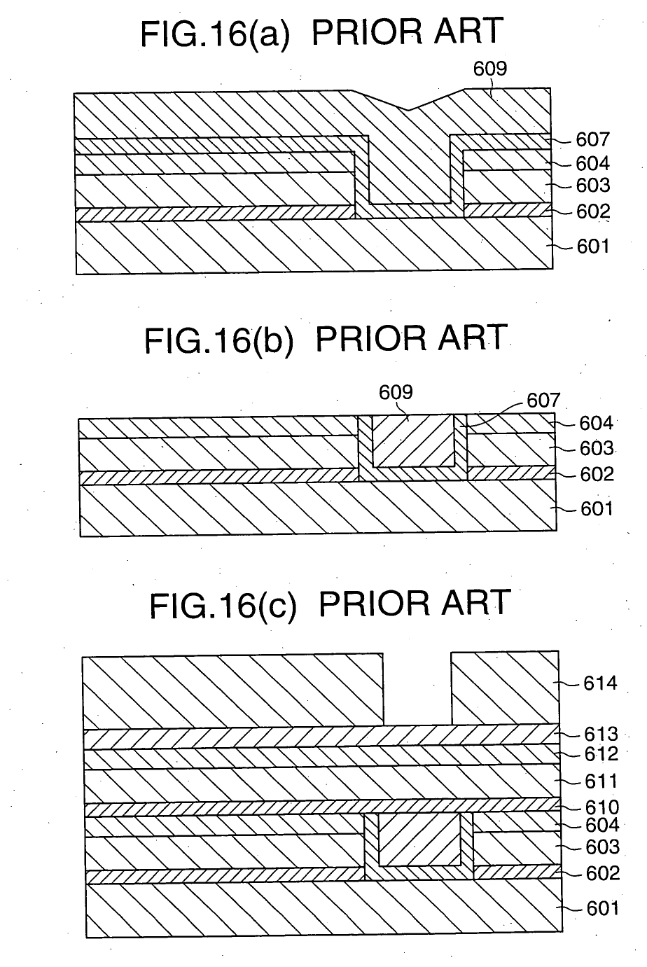

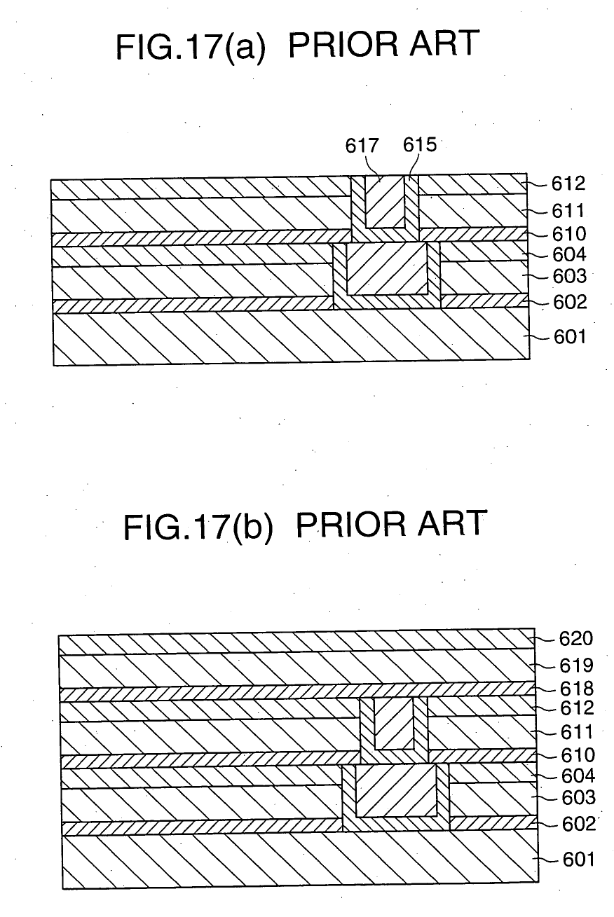

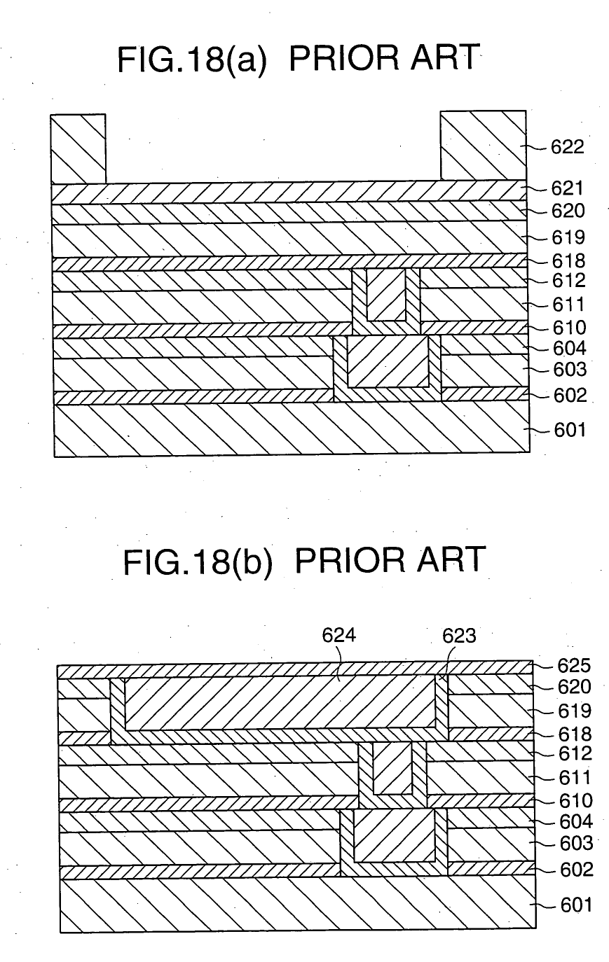

By this method a test was conducted in a case where the nitrogen concentration was varied using samples in which a silicon carbon nitride film was formed on a PSG film. FIG. 12 shows a comparison of spectra before and after the PCT for a structure of SiC/PSG, i.e., a nitrogen concentration of 0 atm %. P═O bonds present before the PCT disappear after the PCT for 96 hours. That is, the function of blocking moisture absorption does not exist in the SiC film. FIG. 13 shows results obtained from a structure of silicon carbon nitride film/PSG (the silicon carbon nitride film in the upper layer and PSG in the lower layer) The nitrogen concentration of this silicon carbon nitride film was 13.8 atm %. In this case it could be ascertained that almost all P═O bonds present before the PCT remain even after the PCT, i.e., the function of blocking moisture absorption of the silicon carbon nitride film could be verified.

Table 1 shows the nitrogen concentration of a silicon carbon nitride film and whether P═O bonds exist after the PCT. When the nitrogen concentration is not less than 10 atm %, almost all P═O bonds remain, and it can be judged that the function of blocking moisture absorption exists in this region. At a concentration of about 8 atm %, the presence of P═O bonds could be ascertained although a decrease in the peak of P═O bonds was somewhat observed. When the nitrogen concentration was below this level, P═O bonds after the PCT could not be ascertained. That is, the function of blocking moisture absorption does not exist.

TABLE 1

| | Nitrogen concentration | | | | |
|---|---|---|---|---|---|
| | (atm %) | | | | |
| | 0 | 5.6 | 8.2 | 10.2 | 13.8 |
| Presence of P═O | x | x | Δ | ∘ | ∘ |
| bonds after PCT | | | | | |

This function of blocking moisture absorption corresponds to the above-described electrical properties. That is, it can be estimated that the function of blocking moisture absorption possessed by a silicon carbon nitride film governs the electrical properties.

Next, the relationship between a barrier metal and a hydrogenated polysiloxane, which is a low-dielectric-constant film, will be described. Table 2 shows the hydrogen concentration of TaN, the occurrence of peeling by metal CMP and the number of dust particles during TaN sputtering in a case where Ta/TaN (Ta: 20 nm in the upper layer and TaN: 10 nm in the lower layer) was used as a barrier metal film.

TABLE 2

| | Nitrogen | | | | | | |
|---|---|---|---|---|---|---|---|
| | concentration (atm %) | | | | | | |
| | 0 | 2.1 | 13.2 | 15.3 | 20.1 | 34.6 | 40.9 |
| Peeling | x | x | Δ | ∘ | ∘ | ∘ | ∘ |
| Number of sputter | 4 | 2 | 3 | 16 | 4 | 15 | >20,000 |
| dust particles | | | | | | | |

On a film having a nitrogen concentration of not less than about 10 atm % determined by the XPS (X-ray Photoelectron Spectroscopy) of TaN, peeling did not occurred in the third embodiment. However, peeling occurred by the CMP of a Cu film when the nitrogen concentration was less than this value. In particular, in a film of not more than 5 atm %, peeling could be visually discerned. At about 8 atm %, peeling could be discerned under an optical microscope although it could not be visually discerned. Incidentally, because in the case of an interlayer dielectric film of SiO₂, peeling did not occur with TaN at any nitrogen concentration, it can be expected that the hydrogen of the hydrogenated polysiloxane is occluded into TaN. Furthermore, the table shows the number of dust particles on an 8-inch wafer during the sputtering of TaN. Particles having a particle diameter of not less than 0.18 μm were counted. Although the number of dust particles was not more than 20 when the nitrogen concentration of TaN was 40 atm %, it increased to not less than 20,000 at a nitrogen concentration exceeding 40 atm % and an overflow occurred.

Table 3 shows the relationship between the embeddability of Cu in a via 0.14 μm in diameter and 0.4 μm in height and the peeling during metal CMP in the barrier metal structure.

TABLE 3

| Structure of | Cu | |
|---|---|---|
| barrier metal | embeddability | Peeling |
| Ta | ∘ | x |
| TaN | x | ∘ |
| Ta/TaN | ∘ | ∘ |

A Cu seed layer of 100 nm was formed on a Ta single layer of 30 nm and a Cu coating of 300 nm was embedded in this Cu seed layer. Embedding after superheating at 450° C. for 12 hours as an accelerated test was checked and no poor embeddability was found. Although there was no problem in the case of Ta (20 nm) /TaN (10 nm) (the same conditions for the Cu on the Ta/TaN), poor embeddability was found in a TaN single layer of 30 nm. The cause of this phenomenon can be explained by the dependency of the Cu film on the base layer. Although the wettability of a Cu film to a Ta film is good, the wettability of a Cu film to a TaN film is poor. It might be thought that this is because there is some relationship between the wettability of Cu and nitrogen. For the peeling of the via Cu by CMP, there was no problem in the case of the laminated Ta/TaN and the TaN single layer, whereas peeling was observed in the case of the Ta single layer. It might be thought that this is because the hydrogen of the hydrogenated polysiloxane is occluded into Ta, deteriorating the metal. It might be thought that the occlusion of hydrogen is suppressed when nitrogen is contained in Ta and that the deterioration of the barrier metal can be prevented.

The barrier metal is not limited to the laminated structure of Ta/TaN. It is necessary only that the structure be such that the H of an interlayer dielectric film having Si—H bonds as an interlayer dielectric film is not occluded thereby to deteriorate the metal. That is, when an interlayer dielectric film having Si—H bonds a barrier metal occluding hydrogen are used, it is necessary only that the structure be such that a layer suppressing the occlusion of H into the interlayer dielectric film is interposed between the two layers. Ti can be mentioned in addition to Ta as a barrier metal which occludes hydrogen. It might be thought that as with TaN, TiN also suppresses the occlusion of hydrogen and that the deterioration of a barrier metal can be prevented by TiN. Therefore, in addition to Ta/TaN, the combinations of Ta/TiN, Ti/TaN and Ti/TiN are also possible.

In the above-described embodiments, an example in which L-Ox, which is a ladder-type hydrogenated polysiloxane, is used as a low-dielectric-constant interlayer dielectric film was shown. However, a cage-type hydrogenated silysesquioxane, which is a type of cage-type hydrogenated polysiloxane, may also be used. However, the effect of interposing a layer which suppresses hydrogen occlusion is somewhat small compared to a case where a ladder-type hydrogenated polysiloxane is used. Furthermore, an equivalent effect was ascertained also in a case where a porous ladder-type hydrogenated polysiloxane having a relative dielectric constant of 2.4 (porous L-Ox). Preferably, a ladder-type hydrogenated polysiloxane or a porous ladder-type hydrogenated polysiloxane is used. Also, it is possible to use a hydrogenated organopolysiloxane formed by the CVD process, which has a smaller effect than hydrogenated polysiloxane, i.e., an insulating film which has both Si—H bonds and Si—CH₃ bonds (the bonds being capable of being ascertained by an FTIR spectrum etc.). Similar results can be obtained with Black Diamond (trade name), Coral (trade name), Aurora (trade name), etc. if trade names are enumerated. Similar results were obtained from MHSQ etc. formed by the application process. It might be thought that the difference in the degree of the above effect is due to the fact that it is more difficult to dissociate the H of Si—CH₃ bonds than the H of Si—H bonds. That is, it was recognized that the more the Si—H bonds of a material, the greater the effect of interposing a layer which suppresses hydrogen occlusion.

As described above, an organosiloxane film (or organosilicate, carbon-containing silicon oxide film) which has no or hardly any Si—H bond has not good adhesion to a TaN film in comparison with an inorganic insulating film, such as a hydrogenated polysiloxane. However, it is possible to give Si—H bonds to these insulating films by a method as described below.

An organosiloxane film not containing Si—H bonds was formed on a base layer containing a Si substrate. The whole surface of the organosiloxane film was subjected to hydrogen plasma treatment from above this film. As a result of this treatment, an organosiloxane film for which Si—H bonds can be identified by the FTIR process could be formed. By using this film and performing the same method as described above, a fabricating method by which poor adhesion between a TaN film and an interlayer dielectric film does not occur could be realized. Although in this example, an organosiloxane film not containing Si—H bonds was described, by performing similar treatment for an organosiloxane film containing few Si—H bonds, it is possible to increase Si—H bonds and hence to improve adhesion. Furthermore, the same effect can be obtained by performing treatment which involves giving energy in a hydrogen atmosphere, such as EB (Electron Beam) treatment, radical treatment and ion implanting, in place of hydrogen plasma treatment as a method of forming Si—H bonds. Although organosiloxane is mentioned here as an example, the same effect can be obtained by using a porous film of organosiloxane.

According to the present invention, even when multilayer interconnection structures of 9 layers of the first to third embodiments were fabricated for 10 months by combinations of an interlayer dielectric film having Si—H bonds and a silicon carbon nitride of a preferred composition, an increase in the capacitance between interconnections did not occur. Furthermore, by interposing, between an interlayer dielectric film and an interconnection layer, a barrier metal film in which a layer suppressing hydrogen absorption is disposed on the side of the interlayer dielectric film, it was possible to perform fabrication without an increase in via resistance and without the occurrence of film peeling.

It is apparent that the present invention is not limited to the above embodiments, but may be modified and changed without departing from the scope and spirit of the invention.

What is claimed is:

1. A semiconductor device, wherein an interlayer dielectric film having Si—H bonds is provided on a base layer including a semiconductor substrate and a silicon carbon nitride film is formed on said interlayer dielectric film.

2. The semiconductor device according to claim 1, wherein an electrically conductive film containing Cu as a main component element is embedded in a trench formed in said interlayer dielectric film and the silicon carbon nitride film is formed on said electrically conductive film.

3. The semiconductor device according to claim 2, wherein said interlayer dielectric film and said electrically conductive film are each formed in a plurality of layers and said silicon carbon nitride film is formed so as to cover said electrically conductive film and said interlayer dielectric film each in a top layer.

4. The semiconductor device according to claim 1, wherein said silicon carbon nitride film has a nitrogen concentration of not less than 10 atm % but less than 35 atm %.

5. The semiconductor device according to claim 2, wherein said silicon carbon nitride film has a nitrogen concentration of not less than 10 atm % but less than 35 atm %.

6. The semiconductor device according to claim 1, wherein said silicon carbon nitride film has a nitrogen concentration of not less than 15 atm % but not more than 30 atm %.

7. The semiconductor device according to claim 2, wherein said silicon carbon nitride film has a nitrogen concentration of not less than 15 atm % but not more than 30 atm %.

8. The semiconductor device according to claim 6, wherein said silicon carbon nitride film contains not less than 22 atm % but not more than 27 atm % Si, not less than 20 atm % but not more than 25 atm % C, and not less than 35 atm % but not more than 45 atm % H.

9. The semiconductor device according to claim 7, wherein said silicon carbon nitride film contains not less than 22 atm % but not more than 27 atm % Si, not less than 20 atm % but not more than 25 atm % C, and not less than 35 atm % but not more than 45 atm % H.

10. The semiconductor device according to claim 4, wherein said silicon carbon nitride film further contains not less than 0.5 atm % but less than 5 atm % O.

11. The semiconductor device according to claim 5, wherein said silicon carbon nitride film further contains not less than 0.5 atm % but less than 5 atm % O.

12. The semiconductor device according to claim 1, wherein said interlayer dielectric film having Si—H bonds is a ladder-type hydrogenated polysiloxane film or a porous ladder-type hydrogenated polysiloxane film.

13. The semiconductor device according to claim 2, wherein said interlayer dielectric film having Si—H bonds is a ladder-type hydrogenated polysiloxane film or a porous ladder-type hydrogenated polysiloxane film.

14. The semiconductor device according to claim 2, wherein a metal nitride film is provided between said interlayer dielectric film and said electrically conductive film containing said Cu as a main component element and a metal film is provided between said electrically conductive film containing said Cu as a main component element and said metal nitride film.

15. The semiconductor device according to claim 2, wherein said electrically conductive film containing Cu as a main component element is a Cu alloy film containing at least one kind selected from the group consisting of Al, Si, Ag, W, Mg, Bi, Zn, Pd, Cd, Au, Hg, Be, Pt, Zr, Ti and Sn.

16. The semiconductor device according to claim 2, wherein said electrically conductive film containing Cu as a main component element is a Cu alloy film containing Si and the Si content is highest on a top surface of the electrically conductive film and gradually decreases with increasing depth in the direction of a bottom surface.

17. A fabricating method of a semiconductor device, comprising:
a first step of forming an interlayer dielectric film having Si—H bonds on a semiconductor substrate;
a second step of forming a trench in said interlayer dielectric film;
a third step of forming a barrier metal film on a side wall and bottom surface of said trench;
a fourth step of embedding an electrically conductive film containing Cu as a main component element in a trench in which said barrier metal film is formed; and
a fifth step of forming a silicon carbon nitride film on said interlayer dielectric film and said electrically conductive film.

18. The fabricating method of a semiconductor device according to claim 17, wherein said third step involves forming a barrier metal film which is formed by sequentially laminating a metal nitride film and a metal film on a side wall and bottom surface of said trench.

19. The fabricating method of a semiconductor device according to claim 17, wherein said electrically conductive film containing Cu as a main component element is a Si-containing film in which a Cu film is subjected to silane treatment.

20. A semiconductor device, wherein an interlayer dielectric film having Si—H bonds and an electrically conductive film containing Cu as a main component element are provided on a base layer including a semiconductor substrate, a metal nitride film is provided between said interlayer dielectric film and said electrically conductive film containing Cu as a main component element, and a metal film is provided between said electrically conductive film containing Cu as a main component element and said metal nitride film.

21. The semiconductor device according to claim 20, wherein said electrically conductive film containing Cu as a main component element is buried in a trench formed in said interlayer dielectric film.

22. The semiconductor device according to claim 20, wherein said metal film is Ta and said metal nitride film is TaN.

23. The semiconductor device according to claim 22, wherein said TaN has a nitrogen content of not less than 15 atm %.

24. The semiconductor device according to claim 22, wherein said TaN has a nitrogen content of not less than 15 atm % but less than 40 atm %.

25. The semiconductor device according to claim 20, wherein said interlayer dielectric film having Si—H bonds is either a hydrogenated polysiloxane film or a hydrogenated organopolysiloxane film.

26. The semiconductor device according to claim 25, wherein said hydrogenated polysiloxane film is a ladder-type hydrogenated polysiloxane film or a porous ladder-type hydrogenated polysiloxane film.

27. The semiconductor device according to claim 20, wherein said electrically conductive film containing Cu as a main component element is a Cu alloy film containing at least one kind selected from the group consisting of Al, Si, Ag, W, Mg, Bi, Zn, Pd, Cd, Au, Hg, Be, Pt, Zr, Ti and Sn.

28. The semiconductor device according to claim 20, wherein said electrically conductive film containing Cu as a main component element is a Cu alloy film containing Si and the Si content is highest on a top surface of the electrically conductive film and gradually decreases with increasing depth in the direction of a bottom surface.

29. A fabricating method of a semiconductor device, comprising:
a first step of forming an interlayer dielectric film having Si—H bonds on a semiconductor substrate;
a second step of forming a trench in said interlayer dielectric film;
a third step of forming a barrier metal film which is formed by sequentially laminating a metal nitride film and a metal film on a side wall and bottom surface of said trench; and
a fourth step of embedding an electrically conductive film containing Cu as a main component element in a trench in which said barrier metal film is formed.

30. The fabricating method of a semiconductor device according to claim 29, wherein said electrically conductive film containing Cu as a main component element is an Si-containing film in which a Cu film is subjected to silane treatment.

31. The fabricating method of a semiconductor device according to claim 29, wherein said first step is a step in which after the formation of an interlayer dielectric film containing Si as a main component element, hydrogen is caused to diffuse to said interlayer dielectric film thereby to form the Si—H bond.

32. The fabricating method of a semiconductor device according to claim 31, wherein said diffusion treatment of hydrogen is any of plasma treatment, electron beam treatment, radical treatment and ion implantation treatment.
